(19) United States
(12) Patent Application Publication
(10) Pub. No.: US 2024/0373622 A1
(43) Pub. Date: Nov. 7, 2024

(54) 3D DRAM Access Transistor

(71) Applicant: Applied Materials, Inc., Santa Clara, CA (US)

(72) Inventor: Tong Liu, Folsom, CA (US)

(73) Assignee: Applied Materials, Inc., Santa Clara, CA (US)

(21) Appl. No.: 18/651,117

(22) Filed: Apr. 30, 2024

Related U.S. Application Data
(60) Provisional application No. 63/499,888, filed on May 3, 2023.

(51) Int. Cl. H10B 12/00; H01L 29/08; H10B 12/10

(52) U.S. Cl. CPC H10B 12/05; H01L 29/0847; H10B 12/03; H10B 12/10; H10B 12/482

(57) ABSTRACT

Disclosed herein are approaches for forming a 3-D dynamic random-access memory device having reduced floating body effect. In one example, a method may include forming a plurality of layers stacked in a first direction, the plurality of layers including a gate layer formed over a first oxide layer, and a source/drain (S/D) layer between a set of gate oxide layers. The set of gate oxide layers may be formed over the gate layer, and the S/D layer may include a source and a drain on opposite sides of a body. The method may further include forming a doped layer over the source and the drain.

### RELATED APPLICATION

This application claims priority to U.S. provisional patent application Ser. No. 63/499,888, filed on May 3, 2023, entitled “3D Dram Access Transistor,” which is incorporated herein by reference in its entirety.

### FIELD OF THE DISCLOSURE

The present disclosure relates to semiconductor structures and, more particularly, to a 3-D dynamic random-access memory (DRAM) transistor with a thinned source and drain for reduced floating body effect.

### BACKGROUND OF THE DISCLOSURE

The manufacturing of dynamic random-access memory (DRAM) cells includes the fabrication of a transistor, a capacitor, and a contact for each of a bit line, a word line, and a reference voltage. In DRAM manufacturing there is a continuous goal of decreasing the size of individual cells and to increase memory cell density to allow more memory to be present on a single memory chip, especially for densities greater than 256 Megabits.

As DRAM devices scale to smaller dimensions, an increasing emphasis is placed on patterning for three dimensional structures, including trenches for storage nodes and access transistors. The lack of body contacts for access transistors creates a floating body effect, however, in which holes accumulate and increase the transient leakage current when bitline voltage changes, for example. This is also seen when a selected bitcell is sensed, when bitline voltage toggles, and/or when an unselected victim bitcell on the same bitline loses charge due to the transient current of floating body effect. The accumulation of such charge loss makes the sensing of a victim bitcell worse, or may even cause the bit data to flip.

One current method to suppress the floating body effect includes adding a body contact in 3D DRAM structures. However, this method significantly increases processing complexity, such as extra doping, interconnects, spacing, and line contacts. It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method of forming a 3-dimensional memory device may include forming a plurality of layers stacked in a first direction, the plurality of layers including a gate layer formed over a first oxide layer, and a source/drain (S/D) layer between a set of gate oxide layers. The set of gate oxide layers may be formed over the gate layer, and the S/D layer may include a source and a drain on opposite sides of a body. The method may further include forming a doped layer over the source.

In another aspect, a method of forming a 3-dimensional dynamic random access memory device may include forming a plurality of layers stacked in a first direction, the plurality of layers comprising a source/drain (S/D) layer between a set of gate oxide layers, wherein the set of gate oxide layers are formed over a gate layer, and wherein the S/D layer includes a source and a drain on opposite sides of a body. The method may further include etching the source and the drain to form thinned portions having a first thickness, wherein the first thickness, in the first direction, is less than a second thickness of the body in the first direction. The method may further include forming a doped layer over the source and over the drain.

In yet another aspect, a memory device may include a plurality of layers stacked in a first direction, the plurality of layers including a gate layer formed over a first oxide layer, a source/drain (S/D) layer between a set of gate oxide layers, wherein the set of gate oxide layers are formed over the gate layer, wherein the S/D layer includes a source and a drain on opposite sides of a body, and wherein a first thickness of each of the source and the drain, in the first direction, is less than a second thickness of the body in the first direction. The memory device may further include a doped layer formed over the source and over the drain.

### BRIEF DESCRIPTION OF THE DRAWINGS

The accompanying drawings illustrate exemplary approaches of the disclosure, including the practical application of the principles thereof, as follows:

FIG. 1 illustrates a side view of a device, such as a 3-D DRAM device, according to embodiments of the present disclosure;

FIG. 2 illustrates a side view of the device during a doping process, according to embodiments of the present disclosure;

FIG. 3 illustrates a side view of the device following formation of a doped layer, according to embodiments of the present disclosure;

FIG. 4 illustrates a side view of an alternative device following formation of a doped layer, according to embodiments of the present disclosure;

FIG. 5 illustrates a side view of the device following a thermal treatment, according to embodiments of the present disclosure;

FIG. 6 illustrates a side view of the device, according to embodiments of the present disclosure;

FIG. 7 illustrates an example flow chart, according to embodiments of the present disclosure; and

FIG. 8 illustrates a diagram of a system or processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity.

### DETAILED DESCRIPTION

Devices, 3-D DRAM transistors, and methods in accordance with the present disclosure will now be described more fully hereinafter with reference to the accompanying drawings, where various embodiments are shown. The devices, 3-D DRAM transistors, and methods may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments herein engineer the source and/or drain of an access device to reduce the current gain of a parasitic bipolar transistor in a 3D DRAM. The band engineering can narrow the emitter bandgap of a source-body-drain n-p-n parasitic bipolar transistor so that the current gain is lower. As a result, floating body can be mitigated when the source-body junction is forward biased. Advantageously, this scheme can be integrated to existing 3D DRAM process flows and, therefore, doesn't require a body contact. Thus, embodiments of the present disclosure can avoid the need for precise contact doping in the body, additional metal lines to connect the body contacts, extra line contacts to route to a power supper, or spacers between the gate/source electrodes and metal interconnects.

In some approaches, the 3-D memory stack may include a gate layer formed over a first oxide layer, and a source/drain (S/D) layer between a set of gate oxide layers, wherein the set of gate oxide layers are formed over the gate layer. The S/D layer may include a source (i.e., bitline contact) and a drain on opposite sides of a body. During processing, the source and/or drain may be thinned (e.g., etched) and then doped (e.g., with germanium) to modify the bandgap. In some embodiments, N-type dopants (e.g., As and/or P) are also doped in the exposed Si of the source and/or drain. SiGe has a narrower bandgap compared to Si, and is easier to integrate in Si DRAM flow. Optimization is further possible by tuning Ge concentration during doping.

A doped layer may be then formed by epitaxially growing SiGe along the thinned Si of the source and drain to form a set of junctions. In some embodiments, the SiGe may be in-situ doped during formation. A dopant activation and junction drive-in process may then be performed, wherein junction location is adjustable by modifying processing temperature and time to control dopant diffusion depth.

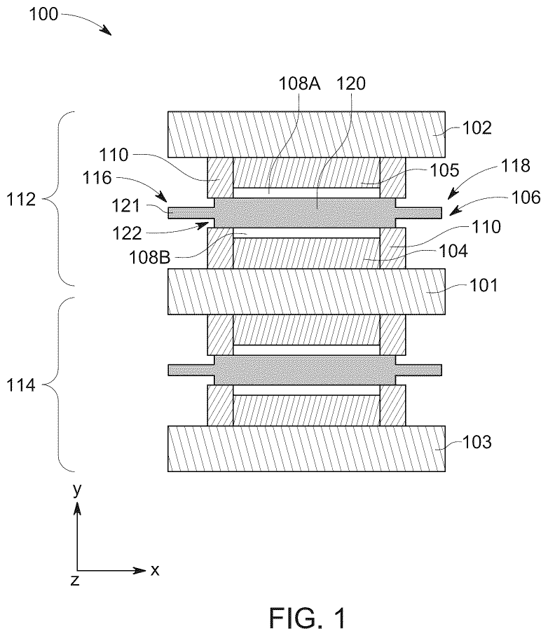

FIG. 1 illustrates a side view of a portion of a transistor or device 100, such as a 3-D DRAM device. As shown, the device 100 may include a plurality of layers stacked vertically in a first direction (e.g., y-direction), wherein the plurality of layers represent a first tier 112 and a second tier 114 of one or more lateral access devices. The first tier 112 of the device 100 may include a first oxide layer 101 and a second oxide layer 102, while the second tier 114 may include a third oxide layer 103. A first gate layer 104 (e.g., metal gate) may be formed over the first oxide layer 101, and a second gate layer 105 may be formed below the second oxide layer 102. A source/drain (S/D) layer 106 may be provided between a set of gate oxide layers 108A and 108B. One or more spacer layers 110 (e.g., nitride) may be formed between the first oxide layer 101 and the second oxide layer 102. More specifically, the spacer layers 110 may be formed on opposite sides of the S/D layer 106.

Although not described in further detail herein, the second tier 114 may have the same or similar layering structure and processing approach as the first tier 112. For example, the second tier 114 may also have a gate layer (e.g., metal gate) and a S/D layer between a set of gate oxide layers. One or more spacer layers (e.g., nitride) may be formed between the oxide layers.

In some embodiments, the S/D layer 106 may include a source 116 and a drain 118 on opposite sides of a body 120. In the embodiment shown, the S/D layer 106 may be silicon (Si), such as a doped silicon, an amorphous silicon, or a polysilicon. The source 116 may correspond to a bitline contact, while the drain 118 may correspond to a SN contact. As shown, the source 116 and the drain 118 may be thinned (e.g., etched) to form a thinned portion 121 having a reduced thickness in the y-direction. In some embodiments, the source 116 and the drain 118 may also be partially recessed in the x-direction to form a gap 122 between the source 116 and the spacer layer 110, and between the drain 118 and the spacer layer 110. In various embodiments, the source 116 and the drain 118 may undergo isotropic etching to reduce the source/drain thickness relative to a thickness of the body 120. In this embodiment, the thickness of the source 116 and the thickness of the drain 118 may be the same. In other embodiments, the thickness of the body 120 may be the same or similar to a thickness of the drain 118, while the source 116 may have a reduced thickness.

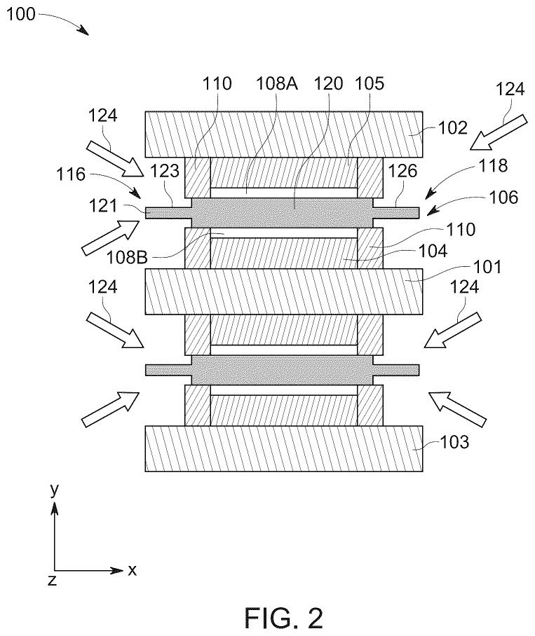

As shown in FIG. 2, an exposed surface 123 of the source 116 and an exposed surface 126 of the drain 118 may then be implanted with a narrow bandgap dopant material 124 (e.g., germanium) using, e.g., a plasma immersion or plasma doping (PLAD) process for bandgap modification. In some embodiments, N-type dopants (e.g., As and/or P) may be doped in the exposed Si of the source 116 and the drain 118 by PLAD as well.

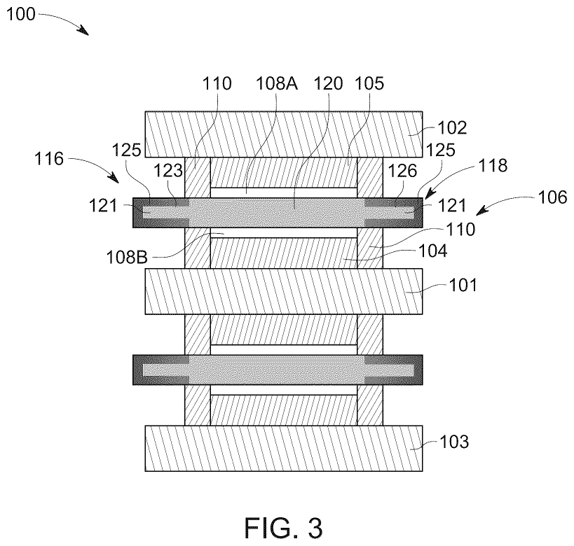

As shown in FIG. 3, a doped layer 125 may then be formed over the source 116 and over the drain 118. More specifically, SiGe may be epitaxially grown over the exposed surface(s) 123 of the thinned portion 121 of the source 116 and over the exposed surface(s) 126 of the drain 118. As shown, the doped layer 125 may be partially formed between the spacer layers 110 and the thinned portions 121 of the source 116 and the thinned portions 121 of the drain 118. It will be appreciated that a ratio of Ge to Si may be modified to adjust the bandgap. In some embodiments, the doped layer 125 may be in-situ doped with N-type dopants during formation. In other embodiments, the doped layer 125 may be formed by chemical vapor deposition (CVD), plasma enhanced CVD, atomic layer deposition, physical vapor deposition, ion implantation, etc.

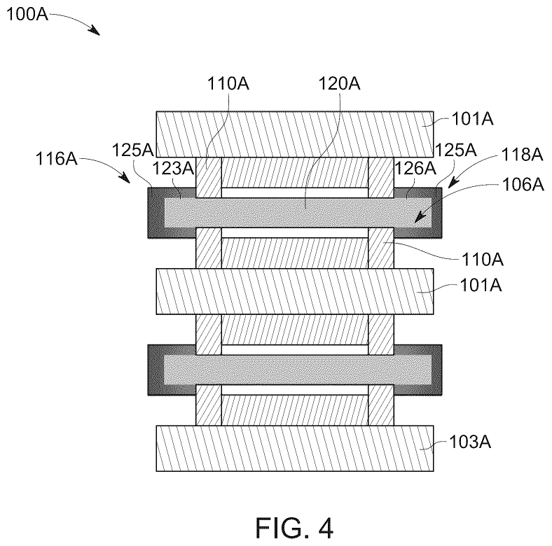

FIG. 4 demonstrates a device 100A according to an alternative embodiment. The device 100A may be the same or similar in many aspects to the device 100 described above. As such, only certain aspects of the device 100A will hereinafter be described for the sake of brevity. An exposed surface 123A of the source 116A and an exposed surface 126A of the drain 118A may be implanted with a narrow bandgap dopant material (e.g., Ge) using, e.g., a plasma immersion or plasma doping (PLAD) process for bandgap modification. In some embodiments, N-type dopants (e.g., As and/or P) may be doped in the exposed Si of the source 116A and in the exposed Si of the drain 118A by PLAD as well. In this case, Si body 120A may be ultra-thin (e.g., 10 nm or below) such that the thinning of the source 116A and/or the drain 118A may be avoided. As shown, doped layer 125A may be formed over the source 116A and over the drain 118A without being formed between spacer layers 110A and S/D layer 106A. Instead the doped layer 125A may be formed partially along a sidewall of the spacer layers 110A. In some embodiments, the doped layer 125A may be SiGe, which is epitaxially grown over the exposed surfaces of the source 116A and the drain 118A.

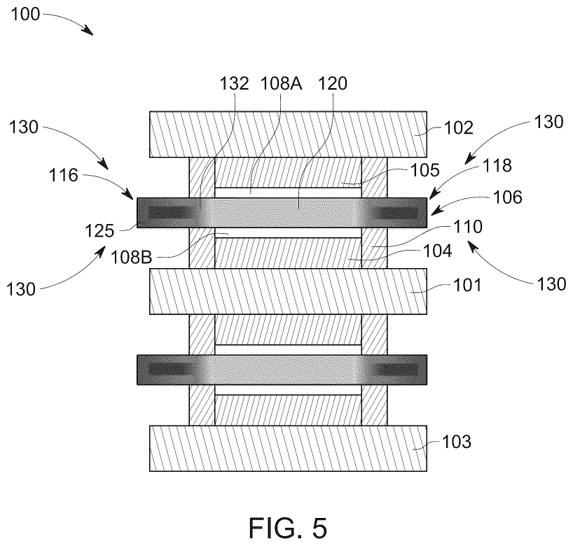

Next, as demonstrated in FIG. 5, the device 100 (from FIG. 3) may be subjected to a thermal treatment 130, such as a rapid thermal anneal, which activates and drives-in dopants of the doped layer 125 into the source 116 and into the drain 118. In some cases, a small portion 132 of the Si p-n junction may exist between the body 120 and the source 116, and between the body 120 and the drain 118, but the floating body effect is still improved. Although non-limiting, the thermal treatment 130 may subject the source 116 and the drain 118 to temperatures between 950-1050° C. The location of the junctions may be adjustable by controlling dopant diffusion depth (e.g., using processing temperature and time).

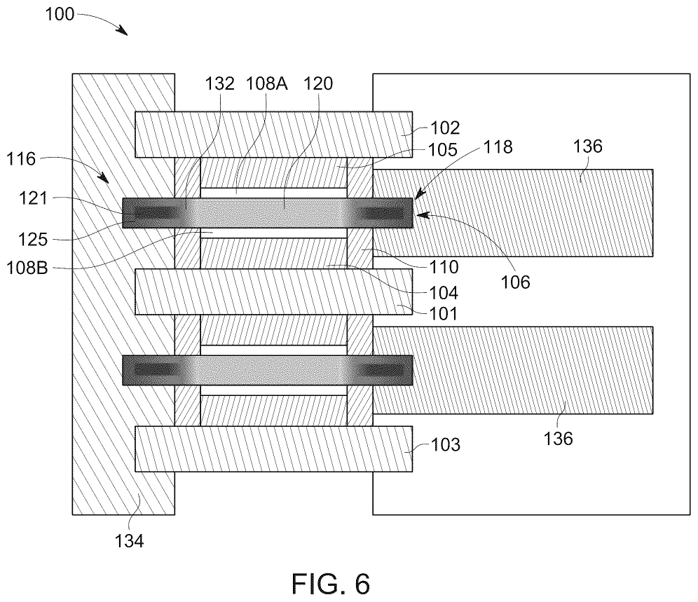

FIG. 6 demonstrates additional structure(s) of the device 100. Although not exhaustive, the device 100 may further include a bitline 134 formed around the doped layer 125 of the source 116, and a capacitor 136 formed around the doped layer 125 of the drain 118. As such, the source 116 may be in electrical communication with the bitline 134 and the drain 118 may be in electrical communication with the capacitor 136. The bitline 134 may include a bit line metal deposited in one or more bit line openings. In various embodiments, the bit line metal may include one or more of WSi, WN, or W, and may be deposited by any suitable technique.

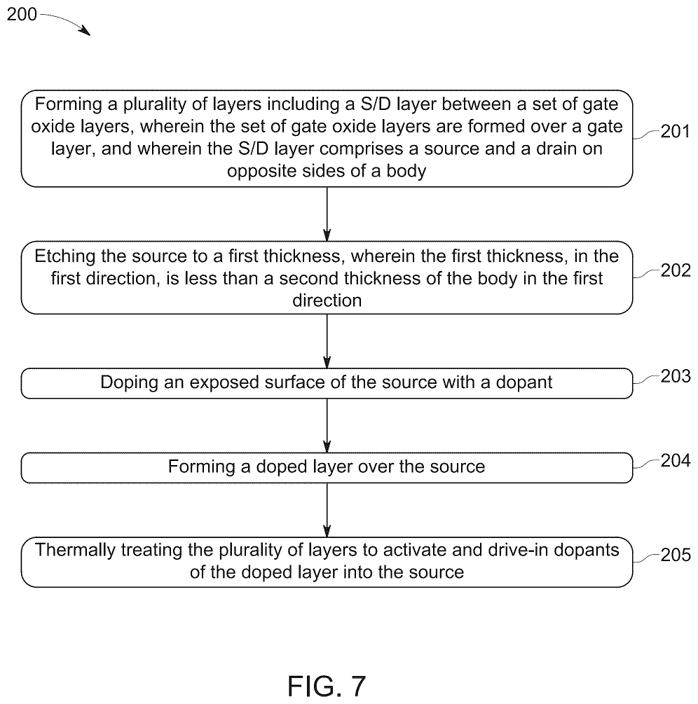

FIG. 7 demonstrates a method 200 for forming a 3-D DRAM device according to embodiments of the disclosure. At block 201, the method 200 may include forming a plurality of layers including a S/D layer between a set of gate oxide layers, wherein the set of gate oxide layers are formed over a gate layer, and wherein the S/D layer includes a source and a drain on opposite sides of a body. In some embodiments, the S/D layer is silicon.

At block 202, the method 200 may include etching the source and the drain to a first thickness, wherein the first thickness, in the first direction, is less than a second thickness of the body in the first direction. The etching may form a thinned portion of the source and a thinned portion of the drain. In some embodiments, isotropic etching can be performed in a suitable etching chamber, such as a plasma etching chamber. In some cases, reducing the thickness of the source is unnecessary, e.g., in the case the S/D layer is ultra-thin (e.g., less than 10 nm). In some embodiments, the source and the drain are symmetrical such that the thinned portion of the source and the thinned portion of the drain have a same or similar thickness. In some embodiments, only the source is thinned.

At block 203, the method 200 may include doping an exposed surface of the source and an exposed surface of the drain with a dopant (e.g., Ge) using, e.g., a PLAD process, for bandgap modification. In some embodiments, N-type dopants (e.g., As and/or P) may additionally be doped in the exposed Si of the source and/or the drain during and/or after the Ge doping.

At block 204, the method 200 may include forming a doped layer over the source and over the drain. In some embodiments, forming the doped layer includes epitaxially growing SiGe over the thinned portion of the source and over the thinned portion of the drain after the thinned portions of the source and drain are doped.

At block 205, the method 200 may further include thermally treating the plurality of layers to activate and drive-in dopants of the doped layer into the source and drain. In some embodiments, the thermal treatment may be a rapid thermal process, such as a rapid thermal anneal.

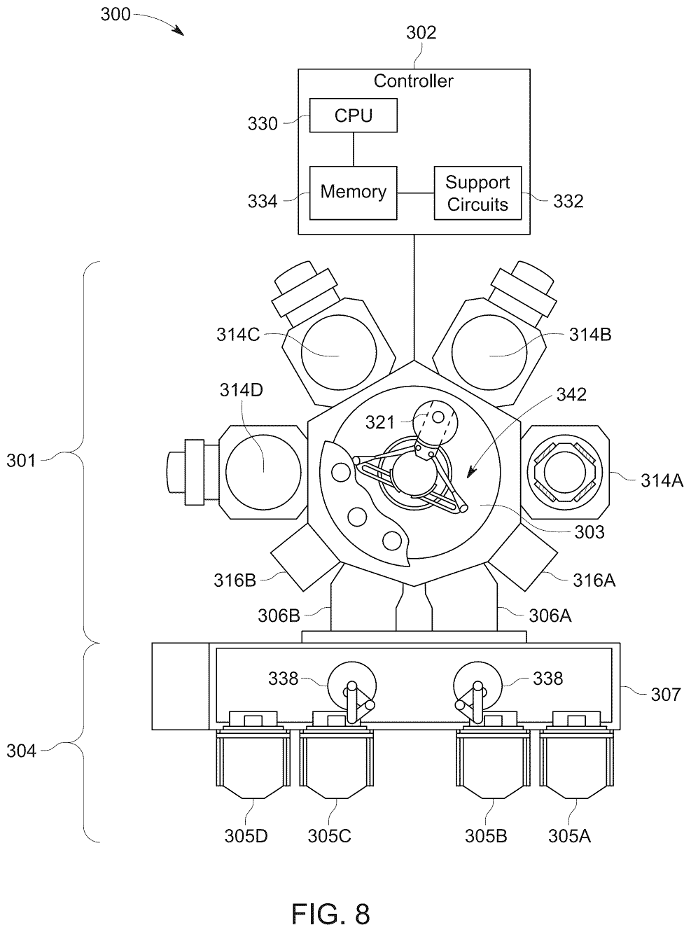

The approaches described above may be performed in a tool, such as an integrated tool or a cluster tool 300, as shown in FIG. 8. The tool 300 may include suitable process chambers configured for one or more of epitaxial growth, dopant delivery, and plasma etching. Exemplary processing systems that may be used to perform the inventive methods disclosed herein may include, but are not limited to, those of the ENDURA®, CENTURA®, CENTURA® PRIME® EPI or PRODUCER® line of processing systems commercially available from Applied Materials, Inc., of Santa Clara, Calif. Other process chambers, including those from other manufacturers, may also be suitably used in connection with the teachings provided herein.

In some embodiments, the tool 300 facilitates operation of the methods described herein with limited or no vacuum breaks between processes. Reduced vacuum breaks may limit or prevent contamination and may further enhance throughput by reducing the amount of time between processes and reducing or eliminating certain processes such as pre-clean operations or other operations that would otherwise be required where the process to be performed sequentially in standalone process chambers.

The tool 300 may include a processing platform 301, a factory interface 304, and a system controller 302. The processing platform 301 may include multiple process chambers 314A, 314B, 314C, and 314D operatively coupled to a transfer chamber 303. The factory interface 304 is operatively coupled to the transfer chamber 303 by one or more load lock chambers, such as 306A and 306B.

In some embodiments, the factory interface 304 includes at least one docking station 307 and at least one factory interface robot 338 to facilitate the transfer of one or more semiconductor substrates 321 (e.g., wafers). The docking station 307 is configured to accept one or more front opening unified pods (FOUP) 305A, 305B, 305C, and 305D. The factory interface robot 338 is configured to transfer the substrates 321 from the factory interface 304 to the processing platform 301 through load lock chambers 306A and 306B. Each of the load lock chambers 306A and 306B have a first port coupled to the factory interface 304 and a second port coupled to the transfer chamber 303. The load lock chamber 306A and 306B are coupled to a pressure control system (not shown), which pumps down and vents the load lock chambers 306A and 306B to facilitate passing the substrates 321 between the vacuum environment of the transfer chamber 303 and the substantially ambient (e.g., atmospheric) environment of the factory interface 304. The transfer chamber 303 may have a vacuum robot 342 disposed within the transfer chamber 303, wherein the vacuum robot 342 is capable of transferring substrates 321 between the load lock chamber 306A and 306B and the process chambers 314A, 314B, 314C, and 314D.

In some embodiments, the process chambers 314A, 314B, 314C, and 314D are coupled to the transfer chamber 303. The process chambers 314A, 314B, 314C, and 314D comprise at least an epitaxial deposition/formation chamber, a plasma doping chamber, and an etch chamber. In some embodiments, at least one deposition chamber is configured to deposit a plurality of layers stacked in a first direction, the plurality of layers including a gate layer formed over a first oxide layer, and a source/drain (S/D) layer between a set of gate oxide layers. The set of gate oxide layers may be formed over the gate layer. The S/D layer may include a source and a drain on opposite sides of a body.

In some embodiments, at least one of the process chambers is an etch chamber configured to etch the source and/or the drain to a first thickness, wherein the first thickness, in the first direction, is less than a second thickness of the body in the first direction. In some embodiments, at least one of the chambers is a plasma doping chamber configured to dope an exposed surface of the source and/or the drain. In some embodiments, at least one of the process chambers is epitaxial deposition/formation chamber configured to epitaxially grow a layer over the source and/or the drain.

In some embodiments, one or more optional service chambers (shown as 316A and 316B) may be coupled to the transfer chamber 303. The service chambers 316A and 316B may be configured to perform other substrate processes, such as degassing, bonding, chemical mechanical polishing (CMP), wafer cleaving, etching, plasma dicing, orientation, substrate metrology, cool down and the like.

The system controller 302 controls the operation of the tool 300 using direct control of the process chambers 314A, 314B, 314C, and 314D or, alternatively, by controlling the computers (or controllers) associated with the process chambers 314A, 314B, 314C, and 314D and the tool 300. In operation, the system controller 302 enables data collection and feedback from the respective chambers and systems to optimize performance of the tool 300. The system controller 302 generally includes a central processing unit (CPU) 330, a memory 334, and a support circuit 332. The CPU 330 may be any form of a general-purpose computer processor that can be used in an industrial setting. The support circuit 332 is conventionally coupled to the CPU 330 and may comprise a cache, clock circuits, input/output subsystems, power supplies, and the like. Software routines, such as processing methods as described above may be stored in the memory 334 (e.g., non-transitory computer readable storage medium) and, when executed by the CPU 330, transform the CPU 330 into a specific purpose computer (system controller 302). The software routines may also be stored and/or executed by a second controller (not shown) that is located remotely from the tool 300.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method of forming a 3-dimensional memory device, the method comprising:
forming a plurality of layers stacked in a first direction, the plurality of layers comprising:
a gate layer formed over a first oxide layer; and
a source/drain (S/D) layer between a set of gate oxide layers, wherein the set of gate oxide layers are formed over the gate layer, and wherein the S/D layer comprises a source and a drain on opposite sides of a body; and
forming a doped layer over the source.

2. The method of claim 1, further comprising forming the source to a first thickness in the first direction, wherein the first thickness is less than a second thickness of the body in the first direction.

3. The method of claim 1, wherein forming the doped layer over the source comprises epitaxially growing the doped layer along the source.

4. The method of claim 3, further comprising doping the source prior to epitaxially growing the doped layer along the source.

5. The method of claim 4, wherein doping the source comprises delivering N-type dopants into an exposed surface of the source.

6. The method of claim 1, further comprising forming a spacer layer between the first oxide layer and a second oxide layer.

7. The method of claim 1, further comprising thermally treating the plurality of layers to activate and drive-in dopants of the doped layer into the source.

8. The method of claim 7, wherein thermally treating the plurality of layers comprises performing a rapid thermal anneal.

9. A method of forming a 3-dimensional dynamic random access memory device, the method comprising:
forming a plurality of layers stacked in a first direction, the plurality of layers comprising a source/drain (S/D) layer between a set of gate oxide layers, wherein the set of gate oxide layers are formed over a gate layer, and wherein the S/D layer comprises a source and a drain on opposite sides of a body;
etching the source and the drain to form thinned portions each having a first thickness, wherein the first thickness, in the first direction, is less than a second thickness of the body in the first direction; and
forming a doped layer over the thinned portions of the source and the drain.

10. The method of claim 9, wherein forming the doped layer over the thinned portions of the source and the drain comprises epitaxially growing a layer of silicon germanium along an exposed surface of the source and along an exposed surface of the drain.

11. The method of claim 9, further comprising doping the thinned portions of the source and the drain with a narrow bandgap material prior to forming the doped layer.

12. The method of claim 9, further comprising doping the source and the drain after the source and the drain are etched by implanting N-type dopants into an exposed surface of the source and into an exposed surface of the drain.

13. The method of claim 9, further comprising forming a spacer layer between the first oxide layer and a second oxide layer.

14. The method of claim 9, further comprising thermally treating the plurality of layers to activate and drive-in dopants of the doped layer into the source and into the drain.

15. A memory device, comprising:
a plurality of layers stacked in a first direction, the plurality of layers comprising:
a gate layer formed over a first oxide layer;
a source/drain (S/D) layer between a set of gate oxide layers, wherein the set of gate oxide layers are formed over the gate layer, wherein the S/D layer comprises a source and a drain on opposite sides of a body, and wherein a first thickness of each of the source and the drain, in the first direction, is less than a second thickness of the body in the first direction; and
a doped layer formed over the source and over the drain.

16. The memory device of claim 15, the plurality of layers further comprising a spacer layer extending between the first oxide layer and a second oxide layer.

17. The memory device of claim 15, wherein the doped layer is an epitaxially grown layer of silicon germanium, and wherein the S/D layer is silicon.

18. The memory device of claim 15, wherein the source and the drain are doped with a narrow bandgap dopant material.

19. The memory device of claim 15, further comprising a bitline in electrical communication with the doped layer of the source.

20. The memory device of claim 15, further comprising a capacitor in electrical communication with the drain.
